(19) United States
(12) Patent Application Publication
(10) Pub. No.: US 2016/0254145 A1
(43) Pub. Date: Sep. 1, 2016

(54) METHODS FOR FABRICATING SEMICONDUCTOR STRUCTURE WITH CONDENSED SILICON GERMANIUM LAYER

(71) Applicant: GLOBALFOUNDRIES INC., Grand Cayman (KY)

(72) Inventors: Dina H. TRIYOSO, Mechanicville, NY (US); Wei Hua TONG, Mechanicville, NY (US); Haoran SHI, Malta, NY (US); Jeremy Austin WAHL, Delmar, NY (US); Amy Lynn CHILD, Wilton, NY (US)

(73) Assignee: GLOBALFOUNDRIES INC., Grand Cayman (KY)

(21) Appl. No.: 14/633,246

(22) Filed: Feb. 27, 2015

(51) Int. Cl. H01L 21/02; H01L 21/225; H01L 29/165; H01L 29/16; H01L 29/161

(52) U.S. Cl. CPC H01L 21/02236; H01L 21/02255; H01L 29/16; H01L 29/161; H01L 29/165; H01L 21/2251; H01L 21/02247

(57) ABSTRACT

Methods of forming condensed first layer and semiconductor structures formed from the methods are provided. The methods include, for instance providing at least one layer disposed over a substrate structure of a semiconductor structure, wherein the substrate structure includes an upper silicon region; and performing at least one oxidation process of the semiconductor structure, the at least one oxidation process reducing a thickness of the upper region, wherein the performing facilitates diffusing to form a condensed layer over the substrate structure.

### BACKGROUND

Semiconductor structures, such as integrated circuits are formed from semiconductor substrates within and upon whose surfaces may be formed electrical elements such as transistors including field-effect transistors (FETs). Conventionally, semiconductor structures make use of silicon as a channel material, but alternative channel materials, such as silicon-germanium and III-V materials, have been considered for improving transistor performance and efficiency. However, several issues persist with integrating such alternative channel materials into semiconductor structure fabrication processes, which may result in the channel material being damaged, contaminated, or destroyed by certain fabrication techniques.

### BRIEF SUMMARY

Certain shortcomings of the prior art are overcome and additional advantages are provided through the provision, in one aspect, of a method which includes, for instance: providing at least one layer disposed over a substrate structure of a semiconductor structure, wherein the substrate structure includes an upper silicon region; and performing at least one oxidation process of the semiconductor structure, the at least one oxidation process reducing a thickness of the upper silicon region, wherein the performing facilitates diffusing to form a condensed layer over the substrate structure.

In a further aspect, a semiconductor structure in one embodiment may be provided which includes a substrate structure with an upper silicon region thereof, the substrate structure including a first region and a second region, wherein the upper silicon region has a first thickness in the first region and a second thickness in the second region, the second thickness being greater than the first thickness; and a first layer disposed over the upper silicon region, and a second layer disposed over the first layer.

Additional features and advantages are realized through the techniques of the present invention. Other embodiments and aspects of the invention are described in detail herein and are considered a part of the claimed invention.

### BRIEF DESCRIPTION OF THE SEVERAL VIEWS OF THE DRAWINGS

One or more aspects of the present invention are particularly pointed out and distinctly claimed as examples in the claims at the conclusion of the specification. The foregoing and other objects, features, and advantages of the invention are apparent from the following detailed description taken in conjunction with the accompanying drawings in which:

FIG. 1A is a cross-sectional elevational view of a semiconductor structure obtained during one embodiment of a semiconductor structure fabrication process, in accordance with one or more aspects of the present invention;

FIG. 1B depicts an alternate embodiment of the structure of FIG. 1A with a nitridation process having been performed over a capping layer, in accordance with one or more aspects of the present invention;

FIG. 1C depicts the structure of FIG. 1A after selectively etching the capping layer in the first region of a substrate structure, in accordance with one or more aspects of the present invention;

FIG. 1D depicts the structure of FIG. 1C with one or more layer(s) having been provided over the substrate structure of the first region, in accordance with one or more aspects of the present invention;

FIG. 1E depicts the structure of FIG. 1D with the first oxidation process having performed to form the oxide layer in the first region, in accordance with one or more aspects of the present invention; and

FIG. 1F depicts the structure of FIG. 1E with the second oxidation process having been performed over the semiconductor structure, in accordance with one or more aspects of the present invention.

### DETAILED DESCRIPTION

Aspects of the present invention and certain features, advantages, and details thereof, are explained more fully below with reference to the non-limiting embodiments illustrated in the accompanying drawings. Descriptions of well-known materials, fabrication tools, processing techniques, etc., are omitted so as to not unnecessarily obscure the invention in detail. It should be understood, however, that the detailed description and the specific examples, while indicating embodiments of the invention, are given by way of illustration only, and are not by way of limitation. Various substitutions, modifications, additions and/or arrangements within the spirit and/or scope of the underlying inventive concepts will be apparent to those skilled in the art from this disclosure.

Disclosed herein, in one embodiment, is an enhanced method for fabricating a semiconductor structure with a condensed first layer such as, condensed silicon germanium layer for p-type field-effect transistors (PFETs) for use, for instance, in the fabrication of integrated circuits such as, fully-depleted silicon-on-insulator (FDSOI) devices. In one aspect, silicon may be used as a channel material in metal-oxide semiconductor field-effect transistors (MOSFETs). However, alternative channel materials have been considered recently to improve transistor performance and efficiency. For example, silicon-germanium (SiGe) may be a desirable channel material that can, for example, be used to improve the threshold voltage of the transistors. As the size of technology nodes continues to decrease, silicon-on-insulator (SOI) transistor devices are currently employed as further enhancements to conventional bulk substrates. By way of example, SOI transistor devices may include, for instance, partially depleted SOI (PD-SOI) devices and fully-depleted SOI (FDSOI) devices. For instance, the FDSOI technology relies on the use of a very thin silicon layer disposed over a buried oxide layer to form the channel region of the transistor.

As noted above, silicon germanium (SiGe) may also be a desirable channel material in the fabrication of FDSOI device, owing to its ability to adjust the threshold voltage of PFETs without affecting the overall device performance. However, conventional fabrication processes currently employed in the fabrication of silicon germanium channel material for PFETs typically involves a germanium condensation technique in which a silicon-rich silicon germanium (SiGe) layer is deposited over a substrate structure. Note that, in this example, the substrate structure may include silicon-on-insulator (SOI) layer disposed over a substrate. A prolonged high temperature oxidation process may be performed to selectively oxidize the silicon atoms and simultaneously, condense the germanium atoms into the underlying silicon-on insulator layer forming the condensed silicon germanium layer, which is rich in germanium, in the PFET region. Disadvantageously, the prolonged oxidation conditions needed to condense the germanium atoms could result in an undesirable increase in the thickness of the germanium-rich silicon germanium layer. Additionally, these prolonged oxidation processes could also result in undesirable oxidation of the thin SOI layer of the n-type field-effect transistors (NFETs). These issues in turn, could cause undesirable process variability which could, for instance, negatively impact performance or yield of integrated circuits containing the FDSOI transistors.

To overcome these issues, generally stated, disclosed herein, in one aspect, is an enhanced method for fabricating a semiconductor structure with a condensed first layer, such as, for instance, germanium-rich silicon germanium layer in the PFET region for use, for instance, in the fabrication of integrated circuits such as, fully-depleted silicon-on-insulator (FDSOI) devices. The method includes, for instance, providing at least one layer disposed over a substrate structure of a semiconductor structure, wherein the substrate structure includes an upper silicon region; and performing at least one oxidation process of the semiconductor structure, the at least one oxidation process reducing a thickness of the upper silicon region, wherein the performing facilitates diffusing to form a condensed layer over the substrate structure.

By way of example, the performing includes performing at least one oxidation process to at least partially oxidize the at least one layer forming an oxide layer and at least one atomic species, the at least one atomic species diffusing to form the condensed layer. In this example, the diffusing of the at least one atomic species consumes an upper silicon region of the substrate structure. For instance, the diffusing of the at least one atomic species may at least partially consume an upper silicon region of the substrate structure. In a specific example, the upper silicon region of the substrate structure has a reduced thickness within a range of about 1 to 3 nm. In one embodiment, the at least one layer may include or be fabricated of a silicon germanium layer, and a protective layer disposed over the silicon germanium layer, and the performing includes performing an in-situ steam growth process to selectively oxidize the protective layer forming an oxide layer. By way of example, the in-situ steam growth process may be performed at a temperature within a range of about 950 to 1100° C.

Further, in another embodiment, the performing may include performing a rapid thermal oxidation (RTO) process to at least partially oxidize the silicon germanium layer to form an oxide layer and at least one atomic species, the at least one atomic species diffusing into the upper silicon surface forming the condensed layer over the substrate structure. By way of example, the rapid thermal oxidation (RTO) process may be performed in the presence of an oxygen process gas, and may be performed at a temperature within a range of about 950 to 1100° C.

In another aspect, the at least one layer may include or be fabricated of a silicon germanium layer having a germanium content of about 15 to 40%, and the performing may include performing an in-situ steam growth process to at least partially oxidize the at least one layer to form an oxide layer and at least one atomic species, with the at least one atomic species diffusing into the upper silicon region to form the condensed layer over the substrate structure. As noted, in one aspect, the at least one oxidation process may be controlled to reduce the thickness of the upper silicon region of the substrate structure. Further, the at least one oxidation process may facilitate inducing an intrinsic strain within the condensed layer disposed over the substrate structure. Note that, in this embodiment, the condensed first layer may include or be fabricated of a germanium-rich silicon germanium layer.

In another embodiment, the substrate structure may include a first region and a second region, with the first region including the at least one layer disposed over the substrate structure, and the providing including providing a capping layer over the upper silicon region of the substrate structure in the second region. The fabricating method may further include performing the at least one oxidation process in the first region, with the capping layer inhibiting oxidizing of the upper silicon region of the substrate structure in the second region, during the at least one oxidation process. In one example, the capping layer may include or be fabricated of at least one of an oxide material, an oxynitride material or a nitride material.

In one example, the capping layer may be or include an oxide material, and the providing may include performing a nitridation process selectively over the capping layer in the second region, with the nitridation process forming at least one of an oxynitrided region within an upper portion of the capping layer or a layer of nitride material over the capping layer. In one aspect of the present invention, the at least one oxidation process may include a first oxidation process, and a second oxidation process, where the at least one oxidation process occurs within a common oxidizing chamber.

In a further aspect, an enhanced semiconductor structure, in one embodiment, is also provided which includes a substrate structure with an upper silicon region thereof, the substrate structure including a first region and a second region, wherein the upper silicon region has a first thickness in the first region and a second thickness in the second region, the second thickness being greater than the first thickness; and a first layer disposed over the upper silicon region, and a second layer disposed over the first layer. As noted, the first layer may include or be fabricated of a condensed silicon germanium layer in the first region, and a first layer may include or be fabricated of a silicon layer in the second region. Further, the first thickness may be less than 3 nm, while the second thickness may be within a range of about 3 to 9 nm.

Reference is made below to the drawings, which are not drawn to scale for ease of understanding, wherein the same reference numbers used throughout different figures designate the same or similar components.

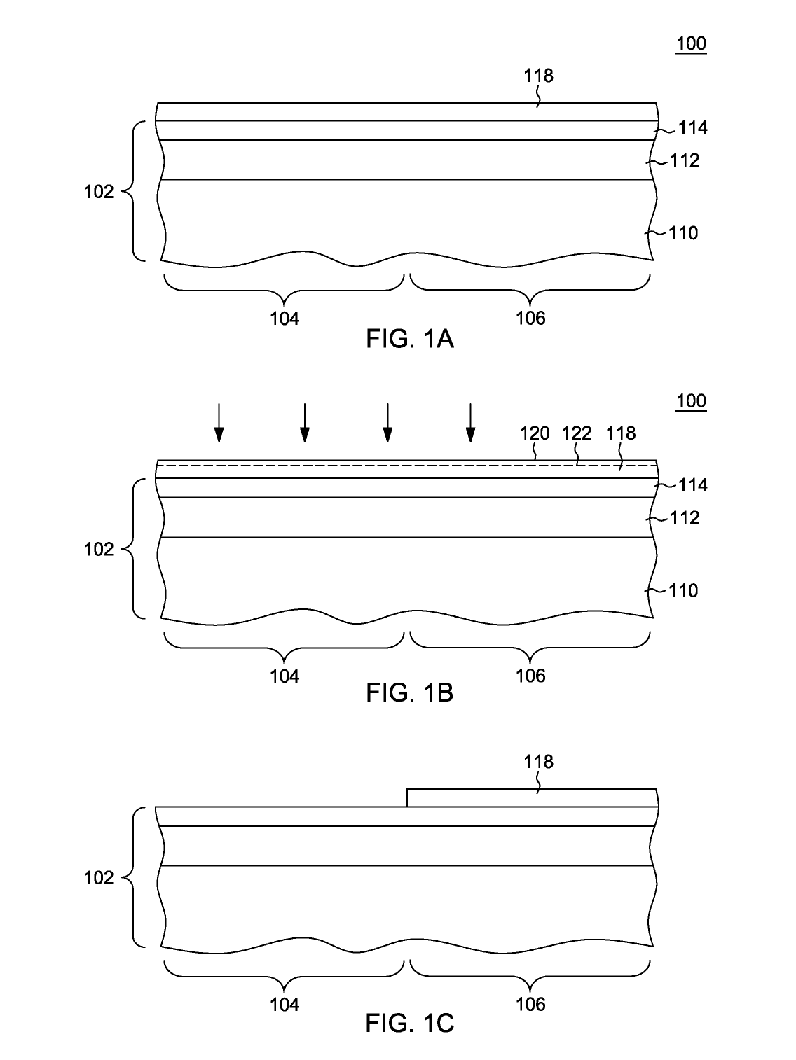

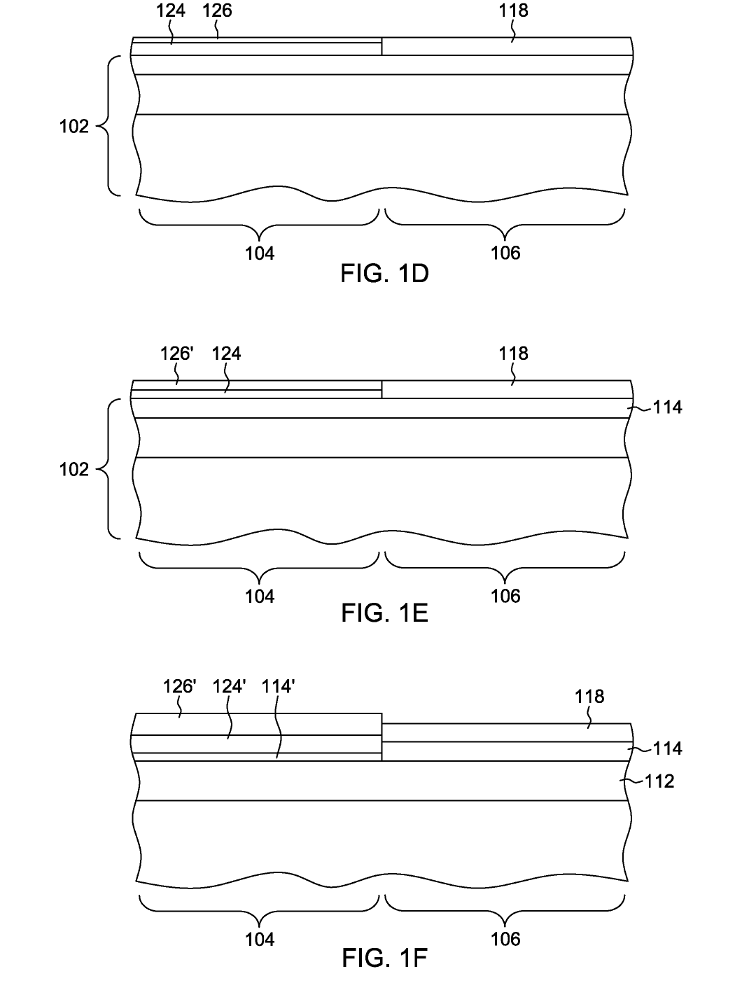

FIG. 1A is a cross-sectional elevational view of a structure 100 obtained during one embodiment of a semiconductor structure fabrication process, in accordance with one or more aspects of the present invention. By way of example, structure 100 includes, for instance, a substrate structure 102. As shown, substrate structure 102 includes, for instance, a first region 104 designated for p-type field-effect transistor (PFET) device and a second region 106 designated for n-type field-effect transistor (NFET) device.

As depicted, in one example, substrate structure 102 may include a substrate 110 which may be (in one example) a bulk semiconductor material such as a bulk silicon wafer. As another example, substrate 110 may be or include any silicon-containing substrate including, but not limited to, single crystal Si, polycrystalline Si, amorphous Si or the like, and may be n-type or p-type doped as desired for a particular application. Substrate 110 may in addition or instead include various isolations, dopings, and/or device features. For instance, the substrate may include other suitable elementary semiconductors such as, for instance, germanium (Ge) in crystal, a compound semiconductor such as silicon carbide (SiC), gallium arsenide (GaAs), gallium phosphide (GaP), indium phosphide (InP), Indium arsenide (InAs), and/or indium antimonide (InSb), or combinations thereof.

Substrate structure 102 may include an electrically insulating layer 112 such as, for instance, buried oxide (BOX) layer disposed over substrate 110. By way of example, in one embodiment, the electrically insulating layer may be or include an oxide material such as, for instance, silicon oxide material, and may be formed using any conventional fabrication processes, for instance, by heating in an oxidizing atmosphere or by oxygen ion implantation as known in the art. In one example, the electrically insulating layer may have a thickness within a range of about 200° A to 250° A, dependent upon the technology nodes in which the semiconductor structure is fabricated. Substrate structure 102 may further include a thin mono crystalline silicon layer 114 (referred to herein as silicon-on-insulator (SOI) layer) which results in an upper silicon region of the substrate structure. The thin silicon layer 114 may have a thickness in the range of about 30 to 90° A, and may be deposited using deposition techniques such as, for instance, atomic layer deposition, chemical vapor deposition, or molecular beam epitaxy. In a specific example, the thin silicon layer may have a thickness of about 70A.

Continuing with FIG. 1A, a capping layer 118 may be provided over substrate structure 102. As used herein, “capping layer” refers generally to a material film or layer which overlies, for instance, substrate structure 102 to protect the substrate structure during subsequent fabrication processing. The capping layer may include or be fabricated of an oxide material such as, for instance, silicon oxide layer. In one example, the capping layer may be grown, for example, by thermal oxidation, and may have thickness in the range of about 5 to 15 nm.

FIG. 1B depicts an alternate embodiment of the structure of FIG. 1A with a nitridation process having been optionally performed over the capping layer, in accordance with one or more aspects of the present invention. In one example, the nitridation process may be performed using a Decoupled Plasma Nitridation (DPN) process, during which an upper surface of capping layer 118 may be bombarded with nitrogen ions, typically generated using a nitrogen source, to form an oxynitrided surface 120 over capping layer 118. In a specific example, an outer surface of capping layer 118 such as, silicon oxide (SiO₂) may be converted to silicon oxynitride (SiON), resulting in oxynitrided surface 120 of the capping layer. In one example, the nitridation process may be performed, in the presence of a nitrogen source such as, ammonia gas (NH₃) at a temperature within a range of about 700 to 1100° C., and for a time period of about 10 to 60 sec. Alternatively, the DPN process may also be performed at a temperature range of about 400° C. to 500° C.

Further, structure 100, including oxynitrided surface 120 of capping layer 118 may optionally be subjected to a post annealing process. This post annealing process, in one embodiment, facilitates diffusing a minimum amount of nitrogen into an upper portion of the capping layer forming oxynitrided region 122 within an upper portion of the capping layer. The oxynitrided region 122 formed within the capping layer from an outer oxynitrided surface may be within a range of about 1 to 15 nm. In yet another alternate embodiment, the nitridation process may also result in forming a thin nitride layer over the capping layer, having a thickness of about 5 to 15 nm.

FIG. 1C depicts the structure of FIG. 1A after selectively etching capping layer 118 in PFET region 104 of substrate structure 102, in accordance with one or more aspects as set forth herein. Although not depicted in the figures, a lithographic photoresist mask may be provided over structure 100 and patterned using any of the conventional lithographic processes, to selectively etch the capping layer resulting in exposing substrate structure 102 in PFET region 104. As noted above, in one example, the capping layer disposed over substrate structure 102 in NFET region 106 may be or include an oxide material such as, silicon oxide (SiO₂). In another example, the capping layer may also be or include an oxide material having an oxynitrided region within an upper portion thereof or a thin nitride layer disposed thereover.

FIG. 1D depicts the structure of FIG. 1C with a layer 124 disposed over substrate structure 102 in PFET region 104, in accordance with one or more aspects as set forth herein. In one example, layer 124 be epitaxially grown or deposited over an upper silicon surface of substrate structure 102, and may be an epitaxial single crystalline semiconductor layer. By way of example, layer 124 may include or be fabricated of a layer of silicon germanium (SiGe), having a germanium content of about 15 to 40%. Layer 124 may be formed (for example) by various epitaxial growth processes such as ultra-high vacuum chemical vapor deposition (UHV-CVD), low-pressure CVD (LPCVD), reduced pressure CVD (RPCVD), rapid thermal CVD (RTCVD), or molecular beam epitaxy (MBE). In a specific example, the selective epitaxial growth of the silicon germanium layer may be performed using halogermanes and silanes as the source gases at temperatures below 600° C. Layer 124 may have a thickness of about 4 to 10 nm, depending upon the metastable thickness of silicon germanium layer.

Continuing with FIG. 1D, a layer 126 may optionally be disposed over layer 124. As used herein, layer 126 may be referred to as protective layer which, for instance, facilitates or protects the silicon germanium layer by at least partially oxidizing to form an oxide layer. Further, in one embodiment, silicon germanium layer 124 and protective layer 126 may together define at least one layer disposed over substrate structure. By way of example, layer 126 may include or be fabricated of a silicon material using, for instance, selective epitaxial growth process. For instance, the selective epitaxial growth process may be used to form layer 126 over the silicon germanium layer which, for instance, may occur using processes such as chemical vapor deposition (CVD) or MBE, and the thickness may be about 1 to 2 nm, by way of example only. In a specific example, layer 126, having a thickness of about 1 nm, may be grown by flowing over the structure a reactant gas, such as dichlorosilane SiH₂Cl₂, trichlorosilane SiHCl₃, silicontetrachloride SiCl₄ or silane SiH₄ together with a carrier gas such as hydrogen gas to form a uniform silicon layer 126. Note that, in one embodiment, the thicknesses of the silicon germanium layer and the silicon layers together in PFET region 104 may be substantially equal to the thickness of capping layer 118 in NFET region 106.

FIG. 1E depicts the structure of FIG. 1D with the first oxidation process having performed to form the oxide layer over silicon germanium layer 124 in PFET region 104, in accordance with one or more aspects of the present invention. By way of example, the first oxidation process may be accomplished, for instance, by performing an in-situ steam growth (ISSG) process to selectively oxidize silicon layer 126 (FIG. 1D) to form oxide layer 126′, for instance, silicon oxide material. In one embodiment of an ISSG process performed on the semiconductor structure, the process is performed at a low pressure, in a cold wall rapid thermal processing reactor chamber. In such an embodiment, hydrogen (H₂) and oxygen (O₂) process gases are introduced directly into the chamber without pre-combustion, and the hot water acts as an ignition source. In one example, the oxidation temperature may be between 950 and 1100° C., and a ratio of H₂:O₂ may be between 1 and 30%. Additionally, the ISSG process may be performed for a time period of about 10 to 300 secs.

As noted, one skilled in the art will know that the difference in sizes of crystalline lattice structures of silicon layer 126 (FIG. 1D) and silicon germanium layer 124 will result in an interface between the two layers to be susceptible to oxidation processes such as, ISSG process. Note that, in this example, silicon layer 126 (FIG. 1D) is selectively oxidized, without affecting the silicon atoms at the interface of the silicon and silicon germanium layers by controlling one or more process parameters employed during the ISSG oxidation process, thereby forming oxide layer such as, silicon oxide layer, having a thickness within a range of about 5 to 15 nm in PFET region 104. Further note that, in one embodiment, the oxide capping layer 118 prevents or inhibits oxidation of substrate structure 102, and in particular, silicon layer 114 in NFET region 106, while in another embodiment, the oxynitrided region or the nitride layer of the capping layer remains inert to the ISSG process, during the oxidation of silicon layer 126 (FIG. 1D) in PFET region 104. In another example, the ISSG process may optionally be prolonged with enhanced process parameters such as, time employed during the oxidation process and/or temperature such that underlying layer 126 may be at least partially oxidized to form an oxide layer such as silicon oxide layer which merges with oxide layer 126′.

In another or alternate embodiment, although not depicted in figures, it may be the case that layer 124 may be provided without the optional layer 126 disposed thereover. In such example, the in-situ steam growth (ISSG) process may be performed directly over layer 124 to at least partially oxidize layer 124 forming an oxide layer such as, silicon oxide layer. Further, the unoxidized germanium atoms (referred to herein as at least one atomic species) diffuse at least partially into silicon layer 114 of substrate structure 102 resulting in consuming at least a portion of silicon layer 114 of substrate structure 102 and forming a condensed silicon germanium layer 124′. Note that, in this embodiment, the process parameters employed in the ISSG process may be controlled to reduce a thickness of silicon layer 114 of substrate structure 102.

FIG. 1F depicts the structure of FIG. 1E with the second oxidation process having been performed over the semiconductor structure, in accordance with one or more aspects of the present invention. By way of example, this second oxidation process may be accomplished, for instance, by performing a rapid thermal oxidation (RTO) process to at least partially oxidize the silicon germanium layer. In one example, the rapid thermal oxidation process may be performed in the presence of process gases such as, for instance, oxygen at a temperature of about 950 to 1100° C. for a time period of about 30 to 300 sec. Note that, in one example, the RTO process may be performed in the same process chamber as the ISSG process by simply changing the respective process parameters.

Further, note that, the rapid thermal oxidation (RTO) process, owing to the difference in chemical affinities between germanium and silicon with respect to oxygen, facilitates at least partially oxidizing the silicon atoms of the silicon germanium layer forming an oxide layer such as, silicon oxide layer leaving, at least in part, the unoxidized germanium atoms. Additionally, the germanium atoms (referred to herein as at least one atomic species) also get diffused at least partially into silicon layer 114 of substrate structure 102 resulting in consuming at least a portion of silicon layer 114 of substrate structure 102 and forming a condensed silicon germanium layer 124′. Note that in one embodiment, while the silicon oxide layer merges with the overlying oxide layer 126′, the condensed silicon germanium layer 124′, which is rich in germanium with a germanium content of about 15 to 40%, may have a thickness within a range of 3 to 10 nm.

Note that as described above, the diffusing of the germanium atoms into silicon layer 114 of substrate structure 102 consumes at least a portion of silicon layer 114 leaving, at least in part, the upper silicon region with a reduced thickness. By way of example, the thickness of silicon layer 114 may be controlled by controlling one or more process parameters such as, for instance, temperature employed in the oxidation process, time duration employed in the RTO process. In one example, the thickness of the upper silicon region, in particular, silicon layer 114 may be reduced to be within a range of about 1 to 3 nm.

Further, one skilled in the art will note that the diffusing of the germanium atoms results in an increase in lattice constant of condensed silicon germanium layer 124′, dependent upon the amount of germanium diffused therein. This increase in the lattice constant of condensed silicon germanium layer 124′ induces an intrinsic strain, in particular, a compressive strain therein. This compressive strain and the resultant stress in PFET region 104 may be modulated by the presence of the thin silicon layer 114 underlying the condensed silicon germanium layer, thereby enhancing an overall device performance. Subsequent gate-last fabrication processing may proceed which includes, for instance, providing isolation layers, patterning of gate structures with sacrificial gate material such as, amorphous silicon (a-Si) or polycrystalline silicon (polysilicon), which may subsequently be replaced with a replacement gate material, providing source and drain regions or the like, etc. In an alternate example, subsequent fabrication processing may also proceed using gate-first fabrication processes using typical process flow, for instance, patterning of gate structures which include, for instance, a metal gate structure, spacer formation, n and p junction formations, and inter-layer dielectric (ILD) deposition or the like, etc.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprise” (and any form of comprise, such as “comprises” and “comprising”), “have” (and any form of have, such as “has” and “having”), “include” (and any form of include, such as “includes” and “including”), and “contain” (and any form contain, such as “contains” and “containing”) are open-ended linking verbs. As a result, a method or device that “comprises”, “has”, “includes” or “contains” one or more steps or elements possesses those one or more steps or elements, but is not limited to possessing only those one or more steps or elements. Likewise, a step of a method or an element of a device that “comprises”, “has”, “includes” or “contains” one or more features possesses those one or more features, but is not limited to possessing only those one or more features. Furthermore, a device or structure that is configured in a certain way is configured in at least that way, but may also be configured in ways that are not listed.

The corresponding structures, materials, acts, and equivalents of all means or step plus function elements in the claims below, if any, are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of one or more aspects of the invention and the practical application, and to enable others of ordinary skill in the art to understand one or more aspects of the invention for various embodiments with various modifications as are suited to the particular use contemplated.

What is claimed is:

1. A method comprising:
providing at least one layer disposed over a substrate structure of a semiconductor structure, wherein the substrate structure includes an upper silicon region; and
performing at least one oxidation process of the semiconductor structure, the at least one oxidation process reducing a thickness of the upper silicon region, wherein the performing facilitates diffusing to form a condensed layer over the substrate structure.

2. The method of claim 1, wherein the performing comprises performing at least one oxidation process to at least partially oxidize the at least one layer forming an oxide layer and at least one atomic species, the at least one atomic species diffusing to form the condensed layer.

3. The method of claim 2, wherein the diffusing of the at least one atomic species consumes the upper silicon region.

4. The method of claim 3, wherein the upper silicon region of the substrate structure has a reduced thickness within a range of about 1 to 3 nm.

5. The method of claim 1, wherein the at least one layer comprises a silicon germanium layer, and a protective layer disposed over the silicon germanium layer, and the performing comprises performing an in-situ steam growth process to selectively oxidize the protective layer forming an oxide layer.

6. The method of claim 5, wherein the in-situ steam growth process is performed at a temperature within a range of about 950 to 1100° C.

7. The method of claim 5, wherein the performing comprises performing a rapid thermal oxidation (RTO) process to at least partially oxidize the silicon germanium layer forming an oxide layer and at least one atomic species, the at least one atomic species diffusing into the upper silicon region to form the condensed layer over the substrate structure.

8. The method of claim 7, wherein the rapid thermal oxidation (RTO) process is performed at a temperature within a range of about 950 to 1100° C.

9. The method of claim 1, wherein the at least one layer comprises a silicon germanium layer, and the performing comprises performing an in-situ steam growth process to at least partially oxidize the at least one layer to form an oxide layer and at least one atomic species, the at least one atomic species diffusing into the upper silicon region to form the condensed layer over the substrate structure

10. The method of claim 1, wherein the at least one oxidation process is controlled to reduce the thickness of the upper silicon region.

11. The method of claim 1, wherein the at least one oxidation process induces an intrinsic strain within the condensed layer disposed over the substrate structure.

12. The method of claim 1, wherein the substrate structure comprises a first region and a second region, the first region including the at least one layer disposed over the substrate structure, and the providing comprises providing a capping layer over the upper silicon region of the substrate structure in the second region.

13. The method of claim 12, wherein the performing comprises performing the at least one oxidation process in the first region, wherein the capping layer inhibits oxidizing of the upper silicon region of the substrate structure in the second region during the at least one oxidation process.

14. The method of claim 12, wherein the capping layer comprises at least one of an oxide material, an oxy nitride material or a nitride material.

15. The method of claim 14, wherein the capping layer comprises an oxide material, and the providing comprises performing a nitridation process selectively over the capping layer in the second region, the nitridation process forming at least one of an oxynitrided region within an upper portion of the capping layer or a layer of nitride material over the capping layer.

16. The method of claim 1, wherein the at least one oxidation process comprises a first oxidation process, and a second oxidation process, and wherein the at least one oxidation process occurs within a common oxidizing chamber.

17. The method of claim 1, wherein the at least one layer comprises at least one of a silicon material or a silicon germanium material, the silicon germanium material having a germanium content of about 15 to 40%, and wherein the condensed layer comprises a germanium-rich silicon germanium layer.

18. A semiconductor structure comprising:
a substrate structure with an upper silicon region thereof, the substrate structure including a first region and a second region, wherein the upper silicon region has a first thickness in the first region and a second thickness in the second region, the second thickness being greater than the first thickness; and
a first layer disposed over the upper silicon region of the substrate structure, and a second layer disposed over the first layer.

19. The semiconductor structure of claim 18, wherein the first layer is a condensed silicon germanium layer in the first region, and wherein the first layer is a silicon layer in the second region.

20. The semiconductor structure of claim 18, wherein the first thickness is less than 3 nm, and the second thickness is within a range of about 3 to 9 nm.
